(19) United States
(12) Patent Application Publication
(10) Pub. No.: US 2007/0002980 A1
(43) Pub. Date: Jan. 4, 2007

(54) Method for timing and sequence hypotheses selection

(76) Inventor: Eyal Krupka, Raanana (IL)

Correspondence Address: PEARL COHEN ZEDEK LATZER, LLP, 1500 BROADWAY, 12TH FLOOR, NEW YORK, NY, 10036, US

(21) Appl. No.: 11/168,431

(22) Filed: Jun. 29, 2005

(51) Int. Cl. H03D 1/04

(52) U.S. Cl. 375/346

(57) ABSTRACT

A method and apparatus may estimate the channel and signal to noise ratio for each of N hypotheses in, for example, a modem or other device receiving data, and may select the hypothesis with the highest signal to noise ratio with a high probability and low computational complexity.

### BACKGROUND OF THE INVENTION

In the field of wireless communications, a first wireless communication station may transmit a first signal to a second wireless communication station via a communication channel. The transmitting signal may be a subject to deterioration in the communication channel with the result that the sequence of symbols received by the receiver is no longer identical to the sequence transmitted. In some cases, the signal may be received by a device such as a modem or another suitable device. The first signal may include a training sequence, e.g., a sequence of symbols known to both the first and second wireless communication stations. The training sequence may be used by the second wireless communication station, for, for example, channel estimation, time tracking, or Carrier to Intetference Ratio (CIR) estimation, or another purpose. The training sequence may be one of a set of training sequences known both to the first and to the second communication station; thus the receiving device may not know which training sequence was used, but may know the set of choices for the training sequence.

EDGE/GSM modems and/or receivers may have or create a set of hypotheses about the identity and content of the training sequence and for example the timing of the training sequence transmitted from a wireless communication station. The receiver may decide which hypotheses best matches the received signal. The algorithms to detect the best match hypothesis for a communication channel may be performed by a processor, for example a digital signal processor (DSP); other suitable processors may be used. The complexity of those algorithms may be high, and thus the processor may perform a relatively high number of computation operations.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features and advantages thereof, may best be understood by reference to the following detailed description when read with the accompanied drawings in which:

FIG. 1 is an illustration of a portion of a wireless communication system according to an embodiment of the present invention;

FIG. 2 is a block diagram of a mobile station according to an embodiment of the present invention;

FIG. 3 is a schematic illustration of a timing diagram of transmission within a wireless communication system according to an embodiment of the present invention; and

FIG. 4 is a flowchart of a method to select the best hypothesis according to an embodiment of the present invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE INVENTION

In the following detailed description, numerous specific details are set forth in order to provide a thorough understanding of the invention. However it will be understood by those of ordinary skill in the art that the present invention may be practiced without these specific details. In other instances, well-known methods, procedures, components and circuits have not been described in detail so as not to obscure the present invention.

Some portions of the detailed description, which follow, are presented in terms of algorithms and symbolic representations of operations on data bits or binary digital signals within a computer memory. These algorithmic descriptions and representations may be the techniques used by those skilled in the data processing arts to convey the substance of their work to others skilled in the alt.

Unless specifically stated otherwise, as apparent from the following discussions, it is appreciated that throughout the specification discussions utilizing terms such as “processing,” “computing,” “calculating,” “determining,” or the like, refer to the action and/or processes of a computer or computing system, or similar electronic computing device, that manipulate and/or transform data represented as physical, such as electronic, quantities within the computing system's registers and/or memories into other data similarly represented as physical quantities within the computing system's memories, registers or other such information storage, transmission or display devices.

It should be understood that the present invention may be used in a variety of applications. Although the present invention is not limited in this respect, the circuits and techniques disclosed herein may be used in many apparatuses such as transmitters and receivers of a radio system. Transmitters and receivers intended to be included within the scope of the present invention include, by way of example only, those used within a wireless local area network (WLAN), a two-way radio system, digital systems or analog systems, cellular radiotelephones and the like.

Types of cellular radiotelephone systems intended to be within the scope of the present invention include, although are not limited to, Code Division Multiple Access (CDMA) and WCDMA cellular radiotelephone portable devices for transmitting and receiving spread spectrum signals, Global System for Mobile communication (GSM) cellular radiotelephone, Time Division Multiple Access (IDMA), Extended-TDMA (E-IDMA), General Packet Radio Service (GPRS), Extended GPRS, and the like.

The term “plurality” may be used throughout the specification to describe two or more components, devices, elements, parameters and the like. For example, “plurality of mobile stations” describes two or more mobile stations. In addition, it should be known to one skilled in the art that the term “portable communication device” may refer to, but is not limited to, a mobile station, a portable radiotelephone device, a cell-phone, a cellular device, personal computer, Personal Digital Assistant (PDA) with communications capabilities, user equipment, and the like.

Some embodiments of the invention may be implemented, for example, using a machine-readable medium or article which may store an instruction or a set of instructions that, if executed by a machine (for example, by stations of wireless communication system, and/or by other suitable machines), cause the machine to perform a method and/or operations in accordance with embodiments of the invention. Such machines may include, for example, any suitable processing platform, computing platform, computing device, processing device, computing system, processing system, computer, processor, or the like, and may be implemented using any suitable combination of hardware and/or software. The machine-readable medium or article may include, for example, any suitable type of memory unit, memory device, memory article, memory medium, storage device, storage article, storage medium and/or storage unit, for example, memory, removable or non-removable media, erasable or non-erasable media, writeable or re-writeable media, digital or analog media, hard disk, floppy disk, Compact Disk Read Only Memory (CD-ROM), Compact Disk Recordable (CD-R), Compact Disk Rewriteable (CD-RW), optical disk, magnetic media, various types of Digital Versatile Disks (DVDs), a tape, a cassette, or the like. The instructions may include any suitable type of code, for example, source code, compiled code, interpreted code, executable code, static code, dynamic code, or the like, and may be implemented using any suitable high-level, low-level, object-oriented, visual, compiled and/or interpreted programming language, e.g., C, C++, Java, BASIC, Pascal, Fortran, Cobol, assembly language, machine code, or the like.

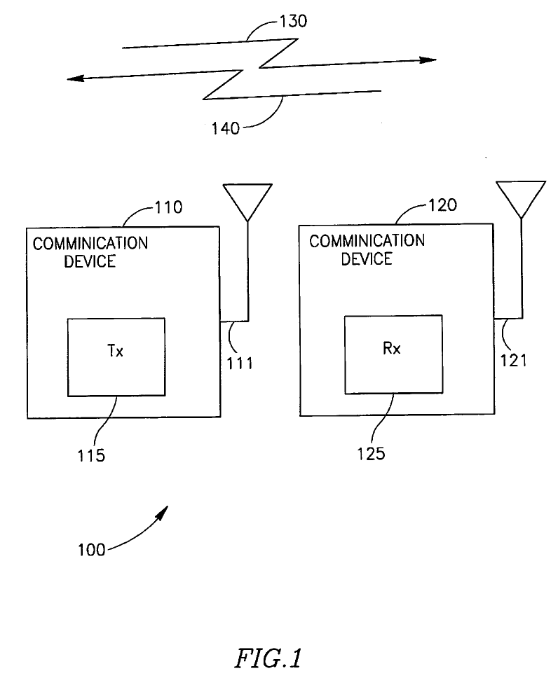

Turning to FIG. 1, a wireless communication system in accordance with an illustrative embodiment of the invention is shown. Although the scope of the present invention is not limited in this respect, wireless communication system 100 may include a communication device 110, a communication device 120, an uplink 130 and a downlink 140. Each of communication devices 110 and 120 may be for example, a cellular base station, a cellular mobile station or any other suitable communication device. Communication device 110 may include a transmitter 115 and communication device 120 may include a receiver 125. In such cases, although the scope of the present invention is in no way limited in this respect, communication devices 110 and 120 may include radio frequency antennas 111 and 121, respectively, as is known in the art.

In some embodiments, receiver 125 and transmitter 115 may be implemented, for example, using separate and/or integrated units, for example, using a transmitter-receiver or transceiver.

Uplink 130 and downlink 140 may be radio or other wireless pathways and may include one or more channels. In accordance with embodiments of the invention, a channel may be for example a physical transfer medium that may be the result of for example reflections and multipath propagation of the transmitted signal. The transmitted signal may reach the receiver having for example different delays and phase shifts, and such distortions may cause the data symbols of the received signal to be influenced by preceding data symbols (e.g. intersymbol interference). The transmitted sequences may include a training sequence which may be for example a sequence known both to the transmitter 115 and the receiver 125. In some embodiments a transmitter 115 may choose to transmit a certain sequence out of a set of sequences known to the receiver 125. The transmitted sequence may be subject to deterioration in the transmission channel, for example, co-channel interference or other interference or deterioration, which may cause the sequence of symbols received by the receiver 125 no longer to be identical to the transmitted sequence. The receiver 125 may have or may develop hypotheses about characteristics of the training sequence, such as the timing and the specific sequence of symbols that may have been transmitted. For example, a hypothesis may include a combination of a certain training sequence out of a set of known training sequences and a certain timing of arrival in reference to a system or other clock, for example the phase of a training sequences arrival relative to clock tics. The receiver 125 may decide which hypothesis best matches the received signal.

In some embodiments of the invention the receiver 125 may select the best hypothesis with typically high probability, using a process having a computational complexity which may be significantly lower than direct methods of selecting the best hypothesis.

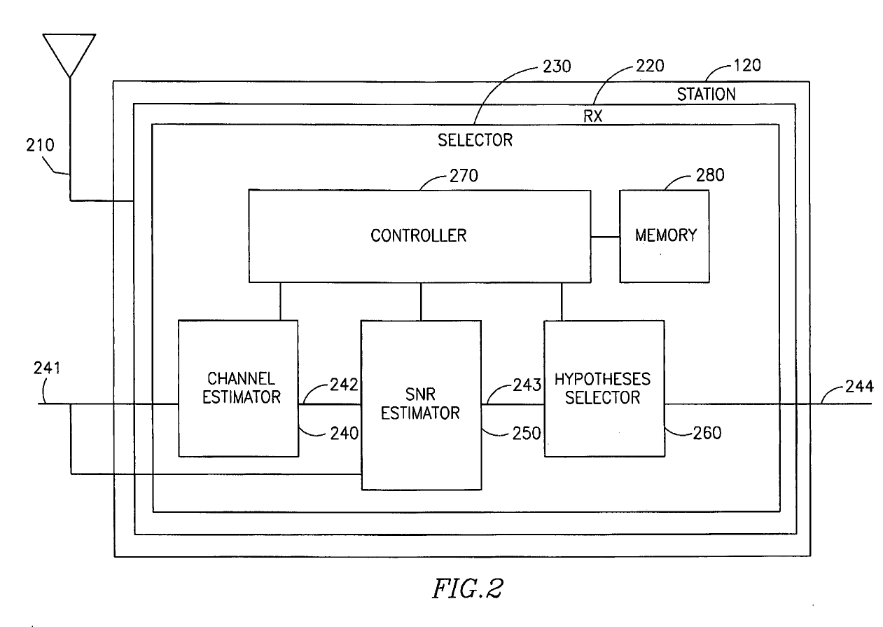

Turning to FIG. 2, a block diagram of a station 120 according to an illustrative embodiment of the invention is shown. Station 120 may be, for example, an implementation of communication device 120 of FIG. 1. Station 120 may include for example an antenna 210, a receiver 220 and a selector 230. In some embodiments of the invention, selector 230 may include a channel estimator 240, a signal-to-noise ratio (“SNR”) estimator 250, a hypotheses selector 260, a memory 280 and a controller 270.

In accordance with some embodiments, selector 230 may be integrated as part of received 220; in alternate embodiments, selector 230 may be implemented using additional and/or alternate hardware components and/or software components. In alternate embodiments, the functionality of one or more units such as receiver 220, selector 230, channel estimator 240, SNR estimator 250, hypotheses selector 260, and controller 270 may be combined into one unit, divided among other units with different nomenclature, or implemented in different manners, such as partially or completely as software executed by a processor.

Antenna 210 may receive a signal that may include one or more data blocks that may be used to estimate the channel information, such as, for example, an impulse response, a training sequence, and the like. Estimating a channel may include estimating or determining such information or possibly other information about a channel.

In some embodiments of the invention, antenna 210 may include for example an internal antenna, an omni-directional antenna, a monopole antenna, a dipole antenna, an end fed antenna, a circularly polarized antenna, a micro-strip antenna, a diversity antenna, a dual antenna, an antenna array or the like. Other suitable antennas may be used.

Selector 230 may select a hypothesis out of a known set of hypotheses, for example N hypotheses. The selected hypothesis may be used for further decoding of the received signal. The hypothesis may be or match to, for example a training sequence, a set of pilot data, or another suitable set of data.

Channel estimator 240 may receive the input signal 241 and may estimate the channel for each one of the N hypotheses by using a first portion or subset of the training sequence's symbols, to produce a set of for example N channel estimations 242. The channel estimator 240 may correlate the N hypotheses with the received training sequence, and may calculate the N impulse responses related to the channel (also referred herein as “channel estimations”). While in one embodiment a channel may be estimated by correlating hypotheses with a received training sequence and calculating the impulse response of the channel, in other embodiments other methods of estimating a channel may be used. For example, the channel estimator 240 may use the first u symbols of the received training sequence. The channel estimator 240 may use any of a variety of different effective channel estimation techniques including, for example, a least squares technique, a linear minimum mean square error (LMMSE) technique, or another suitable technique.

The SNR estimator 250 may receive the N channel estimations 242 and the input signal 241. The SNR estimator 250 may estimate the SNR for each of the N hypotheses using a second portion or subset of the training sequence's symbols (which may for example overlap partially or completely with the portion used to estimate the channel) and the N channel estimations of the N hypotheses. For example, the SNR estimator 250 may use the last k symbols of the received training sequence In other embodiments, the channel and SNR may be estimated using other portions or subsets; for example the channel may be estimated using the last u symbols, and the SNR may be estimated using the first k symbols; a set of symbols selected from the middle of the sequence may be used, etc. Parameters u and k may be equal during some or all iterations.

In one embodiment the channel estimator 240 may use the first u symbols and the SNR estimator 250 may use the last k symbols. The sum u+k may be equal or smaller than the training sequence length which may cause the estimations to be unbiased. In an embodiment where the channel estimation and the SNR estimation each use the whole training sequence, the SNR calculation may be biased; however this may not occur. Furthermore, if u and k are smaller than the training sequence length the computational complexity of the estimations may be lowered. In other embodiments, u+k may be larger than the training sequence length and the channel and SNR estimation portions may partially or completely overlap.

According to some demonstrative embodiments of the invention hypotheses selector 260 may receive the SNR estimations for each one of the N hypotheses 243. The hypotheses selector 260 may select a set (where set may include one item) of hypotheses with the highest SNR. For example, hypotheses selector 260 may drop all hypotheses which have a SNR lower by a constant threshold value than the highest SNR, for example, lower by a parameter or value C from the highest SNR. In other embodiments of the invention the hypotheses selector 260 may keep a constant number of hypotheses; for example, hypotheses selector 260 may keep the L hypotheses with highest SNR. Other methods of selecting hypotheses may be used.

In some embodiments of the present invention the operation of the channel estimator 240, the SNR estimator 250, and the hypotheses selector 260 may be repeated until the hypothesis with the highest SNR is selected. The number of symbols used may be varied from iteration to iteration. In accordance with some embodiments, in an iteration, the channel estimator 240 may update the channel estimation for each one of the hypotheses remaining (e.g. hypotheses which are left after hypotheses selector 260 has dropped or eliminated hypotheses) by for example using a greater portion or subset of the training sequence's symbols than had been used before. For example, the channel estimator 240 may use the first u+m symbols of the received training sequence where m may be a constant or a variable parameter. Furthermore, the SNR estimator 250 may estimate the SNR for each of the surviving hypotheses using a greater portion of the training sequence's symbols than had been used before. For example, the SNR estimator 250 may use the last k+p symbols of the received training sequence, where p may be a constant or a variable parameter. In an illustrative embodiment of the invention the iterations may be done incrementally (e.g. the portions u and k may be incremented on every iteration) using previous results, for example, an LMS algorithm or another suitable algorithm may be used in order to update the channel estimations and SNR estimations. The hypotheses selector 260 may drop the hypotheses with SNR lower by a certain parameter than the highest SNR, based on the same iteration results (e.g., the results of channel estimator 240 and SNR estimator 250 based on greater portions of the training sequence's symbols).

Although the scope of the present invention is not limited in this respect, controller 270 may control the repeated operations of the channel estimator 240, the SNR estimator 250, and the hypotheses selector 260. For example, after the first iteration, controller 270 may send a control signal to channel estimator 240, SNR estimator 250, and hypotheses selector 260 to start an iteration. Furthermore, in accordance with some embodiments, the controller 270 may control the use of the parameters, constants and thresholds, for example, controller 270 may supply the parameters n and m for the channel estimator 240, the parameters k and p for the SNR estimator 250 and the parameters L and C for hypotheses selector 260. In some embodiments controller 270 may be implemented using separate unit; in other embodiments controller 270 may be implemented, for example, using integrated unit, for example, the controller 270 may be integrated into channel estimator 240, SNR estimator 250, and hypotheses selector 260. Other or different parameters may be used.

Although the scope of the present invention is not limited in this respect, the controller 270 may control the tuning of the parameters. For example, a set of parameters may be selected to achieve best trade off between computational complexity and error probability in choosing the hypothesis with the highest SNR

In some embodiments of the present invention memory 280 may store parameters such as C, L, u, k, p and m, and possibly other information. Memory 280 may store the N hypotheses and/or the N of channel estimations and/or SNR estimations. Memory 280 may be a separate unit while in other embodiments memory 280 may be implemented using an integrated unit in, for example, channel estimator 240, SNR estimator 250, and hypotheses selector 260. For example, all the functionality according to one embodiment of the present invention, possibly including a memory, may be in one chip or unit.

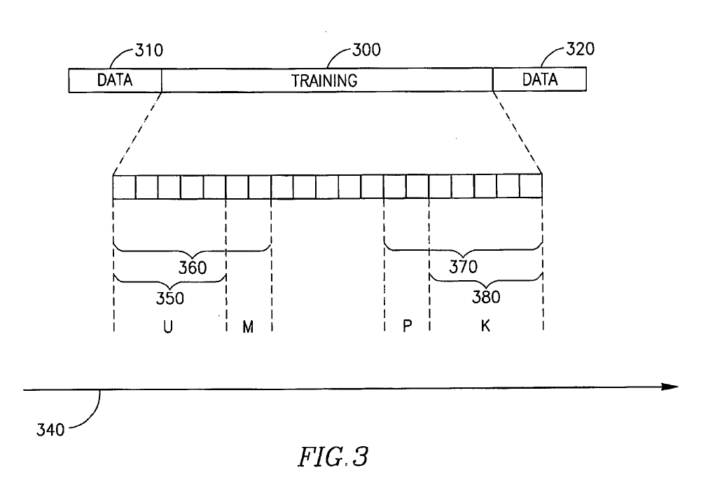

FIG. 3 schematically illustrates a timing diagram of transmission within a wireless communication system according to an embodiment of the invention. Horizontal axis 340 may indicate a time line. In an illustrative embodiment, a device such as station 110 may transmit a signal which may include training sequence 300 and data sequences 310 and 320 (other numbers of data or training sequences may be used, and other or additional data may be sent). The training sequence 300 may include a sequence of symbols, including for example, symbol 330. The training sequence may be located at a point other than that shown within the transmission sequence (for example the training sequence is followed by a data sequence); other numbers of training sequences may be used.

If multiple iterations are used, channel estimator 240 may use the first u symbols 350 of the training sequence 300 during the first iteration, and may use a different number of symbols 260, for example u+m symbols 360 during the second iteration. Similarly, in some embodiments of the invention, the channel estimator 240 may use incremented portions, for example, a set of bits incremented by m symbols on every iteration. Parameter m may be a constant or a variable parameter. SNR estimator 250 may use the last k symbols 380 of the training sequence 300 during the first iteration, and may use k+p symbols 370 during the second iteration. SNR estimator 250 may use incremented portions, for example, incremented by p symbols on every iteration. Parameter p may be a constant or a variable parameter. In accordance with some embodiments of the invention, when the channel estimator 240 and the SNR estimator use all symbols of the training sequence, e.g. u+m is equal to the training sequence length, the hypothesis with the highest SNR may be selected by the hypotheses selector 260. In other embodiments one surviving hypothesis may survive prior to using all the training sequence symbols.

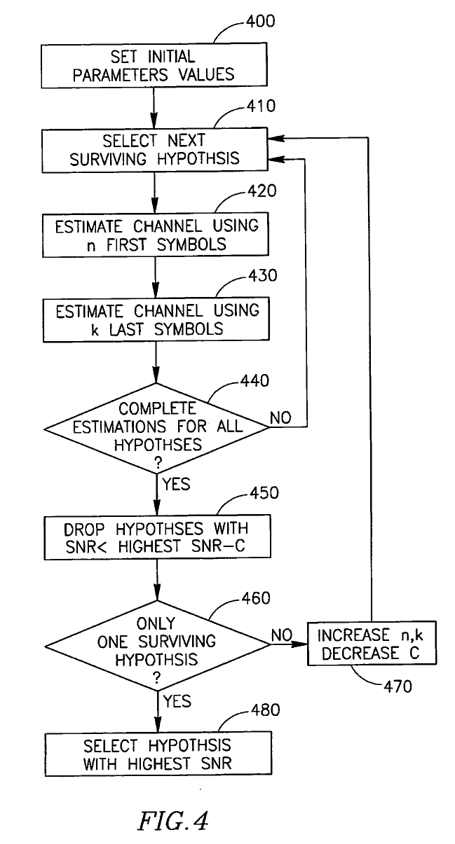

FIG. 4 is a schematic flow-chart of a method of estimating and selecting a hypothesis in accordance with an embodiment of the invention. The method may be used, for example, by one or more of wireless stations 110 and 120 of communication system 100 of FIG. 1, by station 120 of FIG. 2, or by any other suitable wireless communication devices, stations, systems and/or networks. In one embodiment, for example, the method may be used by station 120 upon or during reception of a signal. For example, the method may be initiated upon reception of the training sequence 300 of FIG. 3.

In block 400, the initial parameter values may be set, for example, the initial parameters values of u, k, p, m, L and C. Other or different parameters may be used. The setting may be done by an outside party, for example, a user, a service provided a manufacturer or programmer, the communication network or any other party. In some embodiments the initial parameters may be default initial values set by the station 120 manufacturer or configurer. The initial parameters may be stored in memory 280, controller 270 or another unit of station 120 of FIG. 2.

In block 410, one hypothesis of N hypotheses may be selected and may be stored, for example, in memory 280.

In block 420, the channel may be estimated according to the selected hypothesis and by using only a portion of the training sequence's symbols, for example, by using the first u symbols of the training sequence. In accordance with some embodiments of the invention, the channel estimator 240 of FIG. 2 may estimate the channel.

In block 430, the SNR may be estimated according to the estimated channel and the selected hypothesis. The SNR estimation may use only a portion of the training sequence's symbols, for example, the k last symbols of the training sequence. In some embodiments of the invention, the SNR estimator 250 of FIG. 2 may estimate the SNR.

As indicated in block 440 the channel estimation and the SNR estimation may be repeated for each hypothesis, and may select the next hypothesis if needed as indicated in block 410.

In block 450, all hypotheses with SNR lower by a parameter C from the highest SNR estimated, may be dropped from consideration or eliminated. In some embodiments a constant number of hypotheses, which may have the highest SNR, may be kept for consideration. In accordance with some embodiments of the invention, the hypotheses selector 260 may select which hypotheses may be dropped. In other embodiments, other methods may be used for deciding which hypotheses to keep or to drop.

In block 460, the number of surviving hypotheses may be checked.

In block 470, when more than one hypothesis has survived, the parameters u and k may be increased and parameter C may be decreased.

In block 480, the hypothesis with the highest SNR, which may be the only surviving hypothesis, may be selected.

Other operations or series of operations may be used. In some embodiments, iterations need not be used. Furthermore, parameters need not be altered between iterations, and parameters need not be used. Different methods of choosing hypotheses may be used.

While certain features of the invention have been illustrated and described herein, many modifications, substitutions, changes, and equivalents will now occur to those skilled in the art. It is, therefore, to be understood that the appended claims are intended to cover all such modifications and changes as fall within the true spirit of the invention.

What is claimed is:

1. A method comprising:
estimating the channel for a training sequence received by a receiving device for each of N hypotheses using only a portion of the training sequence's symbols.

2. The method of claim 1, wherein the receiving device is a modem and the training sequence is followed by a data sequence.

3. The method of claim 1, comprising:
estimating the signal-to-noise ratio for each of the N hypotheses using only a second portion of a training sequence's symbols; and
selecting the hypothesis with the best signal-to-noise ratio.

4. The method of claim 1, wherein each of the N hypotheses includes a timing and a sequence.

5. The method of claim 1, comprising:
estimating the signal to noise ratio for each of the N hypotheses using at least a second portion of a training sequence's symbols of the received signal and the N channel estimations of the N hypotheses.

6. The method of claim 1, comprising:
dropping from consideration hypotheses with a signal to noise ratio lower by a parameter from the highest signal to noise ratio.

7. The method of claim 1, comprising:
keeping for consideration a constant number of hypotheses with the highest signal to noise ratio.

8. The method of claim 1, comprising:
repeating the estimating of the channel for each hypothesis using a set of iterations, the estimating on each iteration using a greater portion of a training sequence's symbols than a previous iteration.

9. The method of claim 1, comprising:
repeating the estimating of the signal to noise ratio for each hypothesis using a set of iterations, the estimating on each iteration using a greater portion of a training sequence's symbols than a previous iteration.

10. The method of claim 1, comprising:
repeating estimating the channel and the signal to noise ratio in a set of iterations, and in each iteration dropping a set of hypotheses from consideration based on the signal to noise ratio until only one hypothesis is left.

11. An apparatus comprising:
a channel estimator to, for each of N hypotheses, estimate the channel of a sequence of symbols received by a receiving device using only a portion of the symbols of a training sequence.

12. The apparatus of claim 11, comprising:
a signal to noise estimator to estimate the signal-to-noise ratio for each of the N channel hypotheses using a second portion of the training sequence's symbols; and
a selector to select one or more hypotheses with the best signal-to-noise ratio.

13. The apparatus of claim 11, wherein each of the N hypotheses includes a timing and a sequence.

14. The apparatus of claim 11, comprising:
a signal to noise estimator to estimate the signal to noise ratio for each of the N hypothesis using at least a second portion of a training sequence's symbols of the received signal and the N channel estimations of the N hypotheses.

15. The apparatus of claim 11, comprising:
a selector to drop from consideration hypotheses with a signal to noise ratio lower by a parameter from the highest signal to noise ratio.

16. The apparatus of claim 11, comprising:
a channel estimator to repeat the estimating of the channel for each hypothesis using a set of iterations, the estimating on each iteration using a greater portion of a training sequence's symbols than a previous iteration.

17. The apparatus of claim 11, comprising:
a signal to noise estimator to repeat estimating of the signal to noise ratio for each hypothesis using a set of iterations, the estimating on each iteration using a greater portion of a training sequence's symbols than a previous iteration.

18. A wireless communication system comprising:
a second wireless communication device to transmit a sequence of symbols to a first wireless communication device; and
a first wireless communication device to estimate the channel for each of a set of hypotheses using a portion of the received sequence's symbols.

19. The wireless communication system of claim 18, wherein:
the first wireless communication device includes a signal to noise estimator to estimate the signal-to-noise ratio for each of the N channel hypotheses using a second portion of a received sequence's symbols; and
a selector to select the hypothesis with the best signal-to-noise ratio.

20. The wireless communication system of claim 18, wherein:
the first wireless communication is to estimate the channel using a received training sequence.

21. The wireless communication system of claim 18, wherein:
each of the N hypotheses includes a timing and sequence.

22. The wireless communication system of claim 18 wherein:
the first wireless communication device includes a signal to noise estimator to estimate the signal to noise ratio for each of the N hypothesis using at least a second portion of a training sequence's symbols of the received signal and the N channel estimations of the N hypotheses.

23. The wireless communication system of claim 18, wherein:
the first wireless communication device includes a selector, to drop hypotheses with signal to noise ratio lower by a parameter from the highest signal to noise ratio.

24. The wireless communication system of claim 18, comprising:
a channel estimator to repeat the estimating of the channel for each hypothesis using a set of iterations, the estimating on each iteration using a greater portion of a training sequence's symbols than a previous iteration.
